(19) United States
(12) Patent Application Publication
(10) Pub. No.: US 2012/0031468 A1
(43) Pub. Date: Feb. 9, 2012

(54) SOLAR PANEL SYSTEMS AND METHODS OF USE

(75) Inventors: Sabré Simone du Boise, Panama City Beach, FL (US); Denise C. Donahue, Roswell, GA (US); Daniel F. Downey, Atlanta, GA (US)

(73) Assignee: Cadmus Energy, LLC, Roswell, GA (US)

(21) Appl. No.: 13/274,415

(22) Filed: Oct. 17, 2011

Related U.S. Application Data
(63) Continuation-in-part of application No. 12/943,360, filed on Nov. 10, 2010.
(60) Provisional application No. 61/260,146, filed on Nov. 11, 2009.

(51) Int. Cl. H01L 31/058; H01L 31/052

(52) U.S. Cl. 136/248

(57) ABSTRACT

The present application provides an integrated solar panel system. The integrated solar panel system may include a heat transfer plate, a solar photovoltaic subsystem positioned in part on the heat transfer plate, and a solar thermal subsystem positioned beneath the heat transfer plate. The solar thermal subsystem may include one or more internal concentrator plates positioned about the heat transfer plate.

### RELATED APPLICATIONS

The present application is a continuation-in-part of U.S. patent application Ser. No. 12/943,360, filed on Nov. 10, 2010, entitled “SOLAR PANEL SYSTEMS AND METHODS OF USE,” U.S. patent application Ser. No. 12/943,360 is in turn a non-provisional application claiming priority to U.S. Patent Application Ser. No. 61/260,146, filed on Nov. 11, 2009. U.S. patent application Ser. Nos. 12/943,360 and 61/260,146 are incorporated herein by reference in full.

### TECHNICAL FIELD

The present application relates generally to solar panel systems and more particularly relates to integrated solar panel systems with thin-film photovoltaic collection panels in a lightweight, adjustable racking and mounting frame with solar thermal capability and methods for highly efficient use with maximum energy production.

### BACKGROUND OF THE INVENTION

Solar power is a developing alternative or “green” energy source. Due to the unlimited radiant energy provided by the sun, solar power potentially may replace a significant portion of the non-renewable energy sources currently used for power generation. Widespread adoption of solar power as a significant portion of overall power generation, however, generally has been limited by the initial investment and start-up costs as well as by concerns with overall efficiency in known solar power systems and equipment.

For example, most existing solar power systems use crystalline photovoltaic panels. In addition to the significant weight involved with crystalline panels, the panels may be positioned on a roof or other type of elevated support surface within ballasted racking mounts, which adds even more weight. Due to wind concerns and other reasons, however, many building codes limit the degree of tilt of the crystalline panels to less than the optimum orientation. Although the crystalline panels may be relatively efficient when properly positioned, optimal angles and positions generally are not available. Moreover, the position of the crystalline panels generally is not adjustable such that there may be significant seasonal variations in overall power output.

Certain types of thin-film photovoltaic panels also are in use. Although crystalline panels may be more effective when properly oriented, thin-film panels generally have a broader effective range. Given that the thin-film panels usually are positioned directly on the roof or other type of support structure, however, there also may be orientation issues as well as durability issues with such thin-film panels. As such, neither crystalline panels nor thin-film panels may be particularly efficient in a retrofit installation given the orientation of the existing structure to the sun.

Similarly, certain types of solar thermal panels also are in use to collect solar radiation for water heating and the like. These known solar thermal panels, however, generally are designed and installed separately from solar photovoltaic systems. As such, solar thermal systems and solar photovoltaic systems usually are operated as independent systems and thus may have a number of redundant elements. Moreover, the use of independent solar thermal systems and solar photovoltaic systems requires a considerable amount of limited roof space.

There is thus a desire for improved solar panel systems and methods of use. Such improved solar panel systems and methods preferably should avoid the efficiency issues present in known crystalline panels or thin-film panels while being easy to install and operate. Moreover, such improved solar panel systems preferably may incorporate solar thermal capability into a single system for even higher efficiencies in a reduced overall footprint.

### SUMMARY OF THE INVENTION

The present application and the resultant patent thus provide an integrated solar panel system. The integrated solar panel system may include a heat transfer plate, a solar photovoltaic subsystem positioned in part on the heat transfer plate, and a solar thermal subsystem positioned beneath the heat transfer plate. The solar thermal subsystem may include one or more internal concentrator plates positioned about the heat transfer plate.

The present application and the resultant patent further provide an integrated solar panel system. The integrated solar panel system may include a heat transfer plate, one or more flexible, thin film photovoltaic panels positioned on the heat transfer plate, and a solar thermal subsystem positioned beneath the heat transfer plate. The solar thermal subsystem may include a number of heat exchange coils and one or more internal concentrator plates positioned beneath the heat transfer plate and the heat exchange coils.

The present application and the resultant patent further provide an integrated solar panel system. The integrated solar panel system may include an outer frame, one or more flexible, thin film photovoltaic panels positioned about the outer frame, a solar thermal subsystem positioned within the outer frame, and a pivoting bracket assembly connected to the outer frame. The pivoting bracket assembly may include a pivot bracket and a pivot cradle connected by a pivot strap.

These and other features and improvements of the present application will become apparent to one of ordinary skill in the art upon review of the following detailed description when taken in conjunction with the several drawings and the appended claims.

### BRIEF DESCRIPTION OF THE DRAWINGS

FIG. 1 is a perspective view of a solar panel system as may be described herein.

FIG. 2 is a top plan view of the solar panel system of FIG. 1 showing the components of a photovoltaic subsystem therein.

FIG. 3 is a top plan view of the solar panel system of FIG. 1 showing the components of a solar thermal subsystem therein.

FIG. 4 is a side cross-sectional view of the solar panel system of FIG. 1.

FIG. 5 is a side plan view of a pivoting front bracket assembly that may be used with the solar panel system of FIG.

FIG. 6 is a partial side plan view of a pivoting back bracket assembly that may be used with a solar panel system of FIG. 1.

FIG. 7 is a partial top plan view of the pivoting back bracket assembly of FIG. 6.

FIG. 8 is a schematic view of a solar thermal heating system using the solar panel system of FIG. 1.

FIG. 9 is a side plan view of a pivot bracket positioned about a mounting plate as may be used herein.

FIG. 10 is an exploded perspective view of a ground mount system as may be used herein.

FIG. 11 is a side cross-sectional view of an alternative embodiment of a solar panel system as may be described herein.

FIG. 12 is an exploded perspective view of an alternative embodiment of a pivoting bracket assembly as may be described herein.

FIG. 13 is a side view of the pivoting bracket assembly of FIG. 12.

### DETAILED DESCRIPTION

Referring now to the drawings, in which like numerals refer to like elements throughout the several views, FIGS. 1-4 shows a solar panel system 100 as may be described herein. The solar panel system 100 may include an outer frame 110. The outer frame 110 may be made out of aluminum or other types of lightweight but substantially rigid materials including metals, plastics, composites, and the like. The outer frame 110 may have a C-channel shape 120 in total or in part or similar types of shapes. The outer frame 110 may have any desired length, width, or shape with any number of elements.

The outer frame 110 may define a bottom end 130, a top end 140, a first side 150, and a second side 160. The outer frame 110 also may include a number of reinforcing channels 165 that extend from the top end 140 to the bottom end 130 and/or from the first side 150 to the second side 160. The reinforcing channels 165 also may be made out of aluminum or other types of lightweight but substantially rigid materials including metals, plastics, composites, and the like. Any number or reinforcing channels 165 may be used herein. The outer frame 110, in connection with the other components described below, forms a substantially weatherproof housing with minimal air infiltration. Any number of outer frames 110 may be connected to one another. Other types of frame configurations also may be used herein.

The outer frame 110 also may support a heat transfer plate 170. The heat transfer plate 170 may extend the width of the outer frame 110 from the top end 140 to the bottom end 130 and the length from the first side 150 to the second side 160. The heat transfer plate 170 may be relatively thin in dimension. The heat transfer plate 170 may be made out of aluminum or other types of lightweight, substantially rigid materials with good heat transfer characteristics.

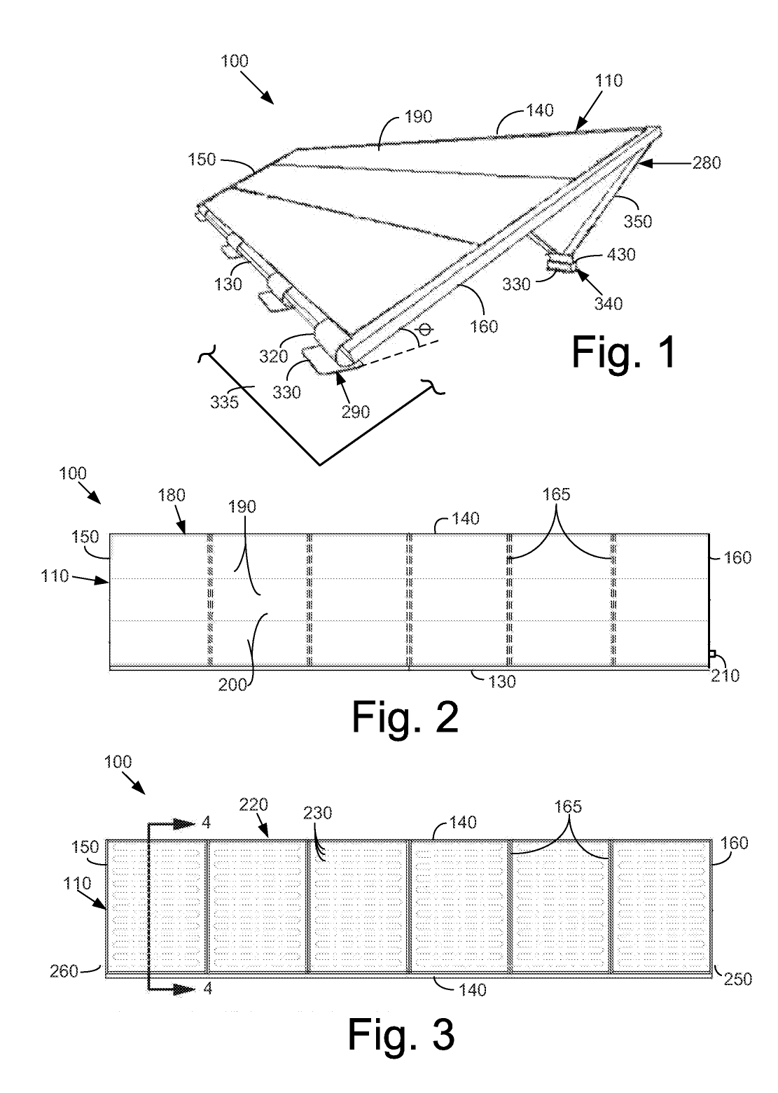

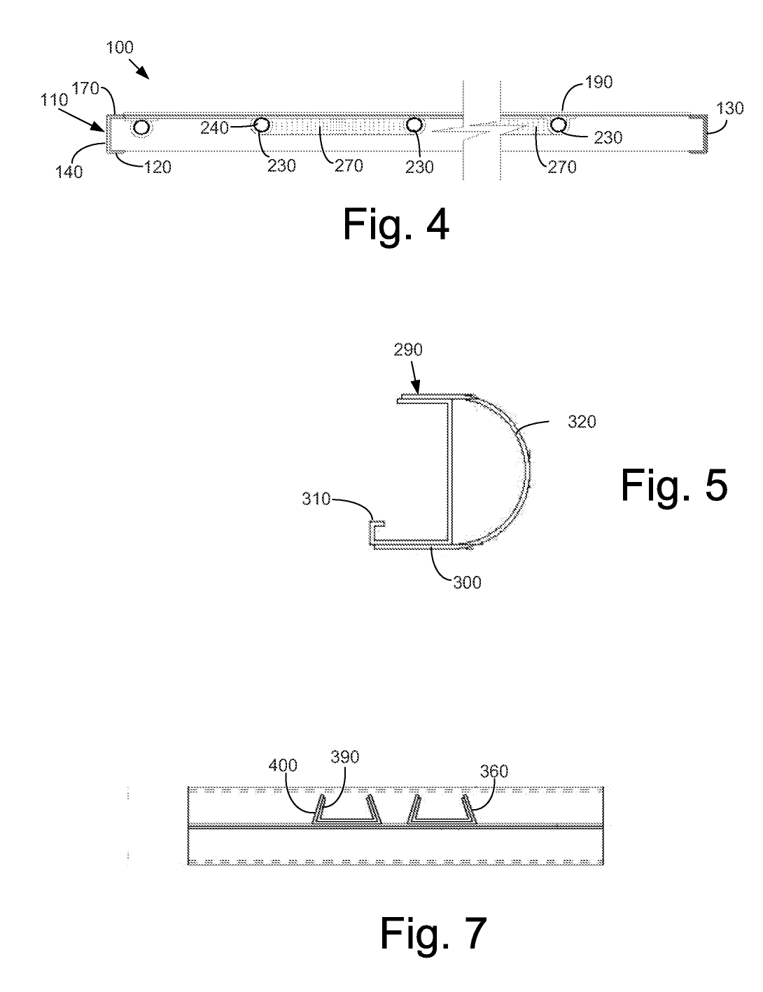

FIGS. 2 and 4 show a photovoltaic subsystem 180 for use with the solar panel system 100. The photovoltaic system 180 includes a number of solar photovoltaic panels 190. The photovoltaic panels 190 may be a number of thin-film or laminate panels 200 positioned on the heat transfer plate 170. In this example, three (3) photovoltaic panels 190 are shown, although any number of panels 190 may be used together. By way of example only, the photovoltaic panels 190 may be sold by United Solar Ovonic LLC of Rochester Hills, Mich. under the “PVL Series” designation. Other types of solar photovoltaic panels 190 may be used herein. For example, various types of nanotechnology may be applied to produce photovoltaic panels and cells as film or coating and the like. This film or coating may be applied to any type of rigid or flexible substrate. The photovoltaic panels 190 produce variable DC power based upon the local weather and other types of operating conditions.

One or more quick disconnect electrical terminals 210 may be positioned about the panels 190. The quick connects 210 may be color coded for ease of installation. Various types of electrical wiring and wiring harnesses also may be used internally or externally herein. One or more sensors also may be used to monitor and regulate the electrical output, temperature, and overall operating conditions. The photovoltaic panels 190 may be in communication with a power conversion system (not shown). The power conversion system generally may include the components required to convert the DC power from the photovoltaic panels 190 to AC power. These components may include a DC to DC converter, a DC to AC inverter 60, and the like. Other types of outputs and configurations may be used herein.

FIGS. 3 and 4 show a solar thermal subsystem 220 that may be used with the solar panel system 100. The solar thermal subsystem 220 may include a number of heat exchange coils 230. The heat exchange coils 230 may be in the form of rigid tubing such as copper or aluminum tubing and the like. Alternatively, the heat exchange coils 230 may be in the form of flexible tubing such as that commercially available from PEX of Sweden under the designation “ThermaPEX” tubing and the like. Other materials may be used herein. Likewise, combinations of materials may be used. For example, flexible tubing with an aluminum thread may be used. Any number of heat exchange coils 230 may be used herein with any number of turns or configurations. The heat exchange coils 230 may have a substantially flat shape for increased surface area and heat transfer. The heat exchange coils 230 may be connected in series or in parallel to a manifold and the like. Other types of heat exchange coil configurations may be used herein.

A heat transfer medium 240 may flow therein. The heat transfer medium 240 may be any type of conventional fluid or gas medium including water, a water-glycol solution, or similar solutions with additives that prevent freezing and/or provide improved performance and the like. The heat exchange coils 230, or each segment of the heat exchange coils 230, may be in communication with a thermal supply 250 at one end and a thermal return 260 at the other. Other types of connection means and other configurations may be used herein.

The heat exchange coils 230 may be positioned underneath the heat transfer plate 170 for contact and heat transfer therewith. The heat exchange coils 230 may be positioned within an insulator 270. The insulator 270 may be made from fiberglass, mineral wool, plastic fiber, polyurethane foam, nitrogen-based urea formaldehyde foam, phenolic foam, cementitious foam, and the like in any orientation or form. Preferably, the insulator 270 may be a non-organic material such as spray foam insulation available from Icynene, Inc. of Ontario, Canada. Other types of insulators and insulating materials may be used herein. Although one example is shown below, the heat generated in the solar thermal subsystem 220 may be used for any purpose.

The solar panel system 100 also may include an adjustable support system 280. The adjustable support system 280 may include a pivoting front bracket assembly 290. As is shown in FIGS. 1 and 5, the pivoting front bracket assembly 290 includes a frame bracket 300 for attaching to the bottom side 130 of the outer frame 110. The frame bracket 300 includes a C-clip 310 on one end to attach to the outer frame 110 in a quick connect fashion. The frame bracket 300 sits within a largely “U”-shaped cup 320 such that the frame bracket 300 and the outer frame 110 may pivot thereabout. The U-shaped cup 320 may be fastened to a mounting plate 330. The mounting plate 330 in turn may be fastened to the roof or other type of support structure 335. Other types of mounting and pivoting elements and configurations may be used herein.

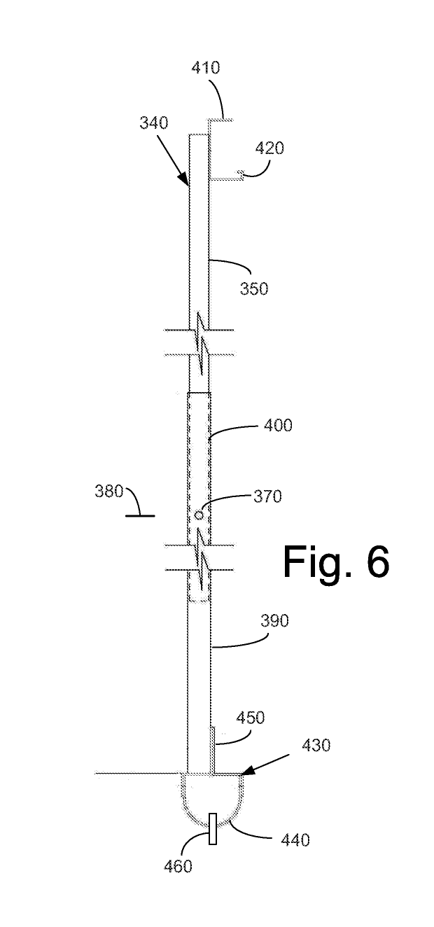

As is shown in FIGS. 1, 6, and 7, the adjustable support system 280 also may include a pivoting back bracket assembly 340. The pivoting back bracket assembly 340 may include a number of adjustable support arms 350. The adjustable support arms 350 may include a number of inter-locking and overlapping “U”-shaped channels 360. The U-shaped channels 360 may include a number of apertures 370 spaced along the length thereof with a locking pin 380 for positioning therein. The height of the adjustable support arms 350 thus may be altered by raising a first channel 390 about a second channel 400 and placing the locking pin 380 into the desired apertures 370. The adjustable support arms 350 have at least two (2) different heights. The adjustable support arms 350 also may include telescoping members, hydraulic members, hinged members, and the like so as to vary the overall length. Other types of adjustable support elements and configurations may be used herein. Other types of mounting and racking systems may be used herein.

The pivoting back bracket assembly 340 also includes a top bracket 410 attached to the adjustable support arms 350. The top bracket 410 may be sized to attach to the top end 140 of the outer frame 110. The top bracket 410 also may include a C-clip 420 for a quick connect with the outer frame 110. Other types of fastening elements and configurations may be used herein.

The pivoting back bracket assembly 340 also may include pivot bracket 430. The pivot bracket 430 may include a bottom U-shaped cup 440 with a top T-section 450. The T-section 450 may be attached to the adjustable support arms 350 via conventional means. The U-shaped cup 440 may be attached to a further mounting plate 330. The U-shaped cup 440 may be attached to the mounting plate 330 via a pivot clip 460 such that the U-shaped cup 440 and the attached adjustable support arm 350 may pivot within the mounting plate 330. Other types of fastening elements, pivoting elements, and configurations may be used herein.

Each pivot bracket 430 may support a pair of adjustable support arms 350. The solar panel system 100 may use any number of the pivot brackets 430 and the adjustable support arms 350. The orientation of the overall solar panel system 100 thus may be varied by extending the length of the adjustable support arms 350 and pivoting the outer frame 110 about the U-shaped cup 320 of the pivoting front bracket assembly 290 and the pivot bracket 430 of the pivoting back bracket assembly 340. Specifically, a tilt angle θ may be varied to at least two different angles. Other types of adjustment means may be used herein. Specifically, although the adjustable support system 280 has been described herein in the context of the pivoting front bracket assembly 290 and the pivoting back bracket assembly 340, any type of structure that allows for the pivoting of the outer frame 110 and the components therein to a desired orientation and tilt angle θ may be used.

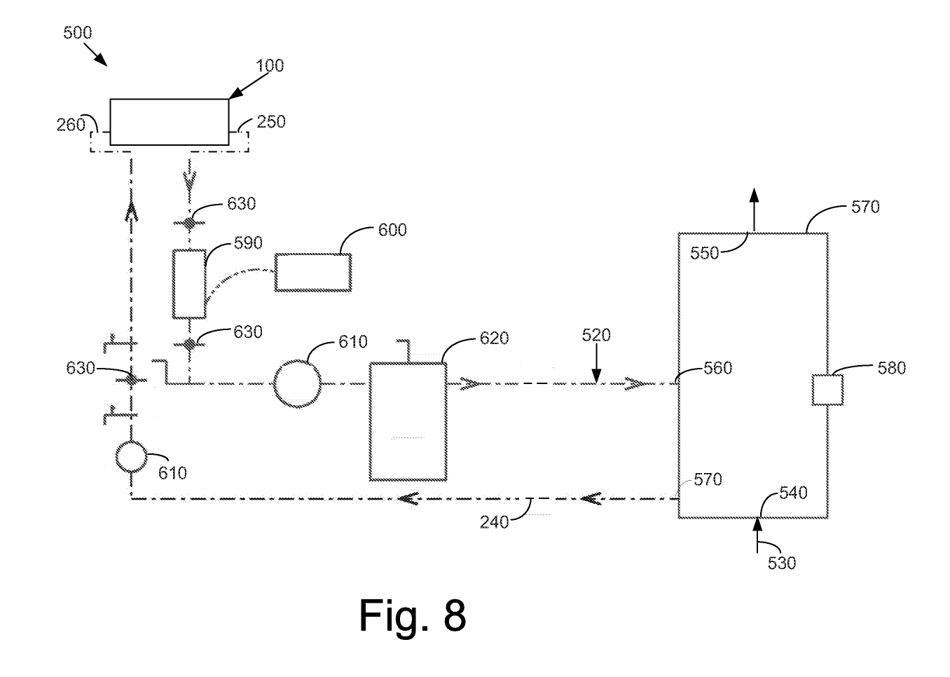

FIG. 8 shows an example of use of the solar panel system 100 with a solar thermal heating system 500. The solar thermal subsystem 220 of the solar panel system 100 may be in communication with a boiler 510 via a thermal circuit 520. The boiler 510 acts as a heat exchanger between the heat transfer medium 240 of the solar thermal subsystem 220 and a secondary water flow 530. Specifically, the boiler 510 may have a secondary water input 540 and a secondary water flow output 550. Likewise, the boiler 510 may have a thermal flow input 560 and a thermal flow output 570 in communication with the thermal circuit 520. The solar thermal heat from the solar panel system 100 thus heats the secondary water flow 530 through heat exchange therewith. An electronic heating element 580 also may be positioned about the boiler 510 to assist in heating the secondary water flow 530 as needed. The heat generated herein may be used for any purpose for domestic, commercial, or industrial use.

Various other components also may be used with the solar thermal circuit 520. For example, the thermal return 260 of the solar thermal subsystem 220 may be in communication with a pump 590. The pump 590 may be of conventional design. Operation of the pump 590 may be controlled by an electronic control unit 600 such that the heat transfer medium 240 may be circulated at specific boiler temperatures. The electronic control unit 600 also may operate in conjunction with a pressure and temperature gauge 610. The pressure and temperature gauge 610 may be of conventional design and may monitor the temperature and pressure of the heat transfer medium 240. An expansion tank 620 also may be used to regulate the pressure within the solar thermal circuit 520. The expansion tank 620 may be of conventional design. The solar thermal circuit 520 also may include a number of other pressure gauges 610 as well as any number of flow valves 630. Other types of flow and control elements may be used herein in any orientation. The solar panel system 100 does not necessarily need to include the solar thermal subsystem 220 or the solar thermal heating system 500. Other heating configurations may be used herein.

In use, the solar panel system 100 described herein is easy to install as a retrofit or as original equipment. Specifically, the outer frame 110 with the photovoltaic subsystem 180 and the solar thermal subsystem 220 is relatively flat such that shipping to the instillation location may be relatively easy and inexpensive. Moreover, the use of aluminum for the outer frame 110 also makes transport relatively easy. The components herein may be delivered as a kit and in either standard or custom sizes.

Once onsite, the mounting plates 330 may be attached to the roof or other type of support structure 335. The pivoting front bracket assembly 290 may be fastened thereto and the outer frame 110 may be positioned therein. The C-clip 310 of the frame bracket 400 makes for quick installation. Likewise, the pivoting back bracket assembly 340 may be installed by attaching the pivot bracket 430 to the mounting plate 330 via the pivot clip 460. The adjustable support arms 350 thus may be extended to the desired height and locked into place via the apertures 370 and the locking pin 380. The top bracket 410 then may be attached via the C-clip 420. The solar panel system 100 thus may be positioned at the desire tilt angle θ. The tilt angle θ may be about ten degrees) (10° to about twenty-eight degrees (28°). Other angles may be used herein. The tilt angle θ may be varied to at least two different angles. The outer frame 110 and the solar panel system 100 as a whole may comply with ASCE-7 section 6.1.4.2 concerning wind design and chapter 13 concerning seismic design. Significantly, the tilt angle θ also may be changed seasonally or otherwise such that the solar panel system 100 may be positioned at the optimal angle. The solar panel system 100 also provides passive shading/cooling to the roof or other support structure.

The photovoltaic subsystem 180 then may be connected electrically via the quick disconnect electrical terminals 210. Depending upon the size of the overall solar panel system 100, the photovoltaic subsystem 180 may generate about 144 watts or more per panel (about 288 watts or more for two (2) panels, about 432 watts or more for three (3) panels, about 576 watts or more for four (4) panels, etc.) Any number of panels 190 may be used herein. Bypass diodes also may be used for shadow tolerance.

The solar thermal subsystem 220 then may be connected to the thermal circuit 520 via the thermal supply 250 and the thermal return 260. Additional quick connects may be used with integrated automatic shut off valves. The solar thermal subsystem 220 thus may heat the secondary water flow 530 to provide on demand hot water. The heat generated by the solar thermal subsystem 220 may be used for any purpose. The heat transfer medium 240 also serves to cool the photovoltaic subsystem 180 so as to increase overall power production. Moreover, use of the greater tilt angle for the solar power system 100 as a whole as described above also provides increased cooling for the photovoltaic system 180 given that the thin film panels 200 are not position directly on the roof or other structure. The solar panel system 100 thus provides the photovoltaic subsystem 180 and the solar thermal subsystem 220 in the same footprint of a typical photovoltaic panel system. Such a combination provides increased overall energy production and efficiency. The solar panel system 100 also is easy to remove and/or upgrade.

The combination of the thin film panels 200, the solar thermal subsystem 220, and the adjustable support system 280 thus results in an overall solar panel system 100 that may have a DC to AC derate factor of about 1.0 or higher. The overall DC-to-AC derate factor accounts for losses from the DC nameplate power rating of the panels 200 and is the mathematical product of the derate factors for the components of a photovoltaic system. Moreover, the combination of the outer frame 110 with the photovoltaic subsystem 180 and the solar thermal subsystem 220 may be less than about 1.5 pounds per square foot (about 7.3 kilograms per square meter). As such, the system 100 provides high power output at a low weight.

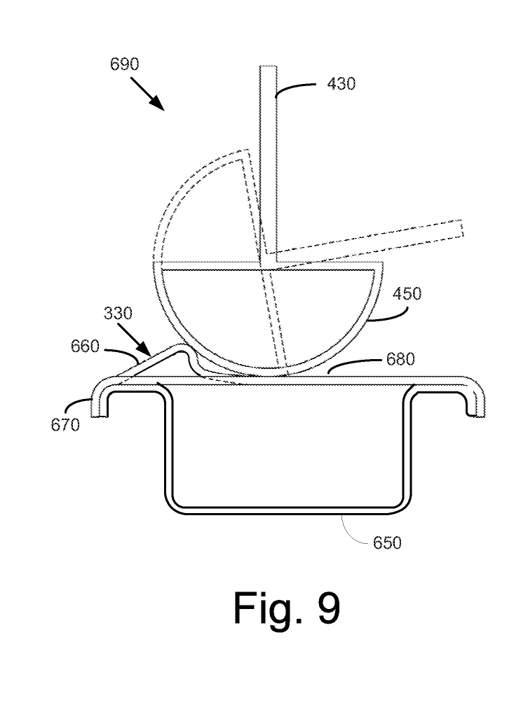

Although the use of the pivoting back bracket assembly 340 about the mounting plate 300 was described above, FIG. 9 shows further details of one example of the mounting plate 330. The mounting plate 330 may include a bottom cup 650 enclosed by an upper cap 660. Both the cup 650 and the cap 660 may include a largely U-shaped rim 670. The cap 660 may define a pivot path 680 positioned therein. Other configuration may be used herein.

In use, the mounting plate 330 may be attached to the roof 335 or other type of support structure by fastening the lower cup 650 directly thereto. The upper cap 660 may be fitted thereon. The pivot bracket 430 then may be positioned about the pivot path 680. The pivot clip 460 may extend through the U-shaped cup 450 of the pivot bracket 430 and attach about the rim 670. Other configurations may be used herein. The mounting plate 330 thus provides for easy and quick installation. Likewise, the use of the cap 660 also provides a largely waterproof instillation. The pivoting of the pivot bracket 430 within the pivot path 680 is shown. The use of the mounting plate 330 thus describes one example of a roof based mounting system 690.

The overall solar panel system 100 also may be used without the adjustable port system 280 and the like. Rather, the outer frame 110 with the photovoltaic subsystem 180 positioned therein also may be positioned directly about a roof or other type of support structure 335. For example, the pitch of the roof may be sufficient for adequate electrical output. Likewise, non-adjustable support systems also may be used herein. Although flat or angled support surfaces have been described herein, the solar power system 100, and components thereof, also may be mounted on walls and other types of substantially vertical structures.

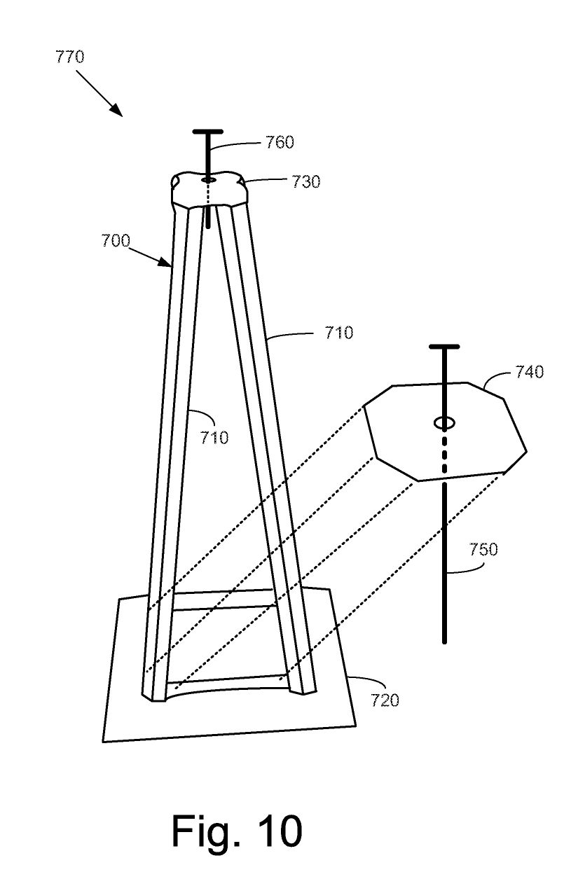

FIG. 10 shows an example of an alternative mounting system using a number of ground mounts 700. The ground mounts 700 may include a number of stanchions 710 positioned on a mounting plate 720. In this example, four (4) stanchions 710 are used although any number may be used herein. The stanchions 710 may have any height. The stanchions 710 extend to a leveling plate 730. An anchor plate 740 may be positioned about the mounting plate 720 and one or more earth anchors 750 may extend therethrough. The earth anchor 750 may be an extended rod for anchoring the ground base mounting system 700 within the earth. Likewise, a threaded rod 760 may extend through the leveling plate 730. The threaded rod 760 may be attached to the aluminum outer frame 110. The position of the threaded rod 760 may be varied such that the angle of the outer frame 110 may be varied as desired. A number of the ground mounts 700 may be used together as a ground base mounting system 770. Other configurations may be used herein.

In use, a number of the ground mounts 700 may be anchored into the earth via the earth anchor 750. The desired length of the threaded rod 760 may be determined and the outer frame 110 may be attached. The desired tilt angle also may be changed by changing the length of the threaded rod 760. The ground base mounting system 770 has the advantage of being largely prefabricated and may be installed without the use of concrete. As such, the ground base mounting system 770 thus may be preferred for use in wetlands or other types of remote locations in that welding equipment, concrete trucks, and other types of heavy equipment need not be used. Further, because of the use of the stanchions 710, the overall solar power system 100 is elevated off of the ground at any desired length. As such, the photovoltaic panels 190 will not be interfered with by, for example, tall grasses or flying debris from mowed grass. Likewise, the elevation largely avoids interaction with wildlife. Other configurations and other types of mounting and racking systems may be used herein.

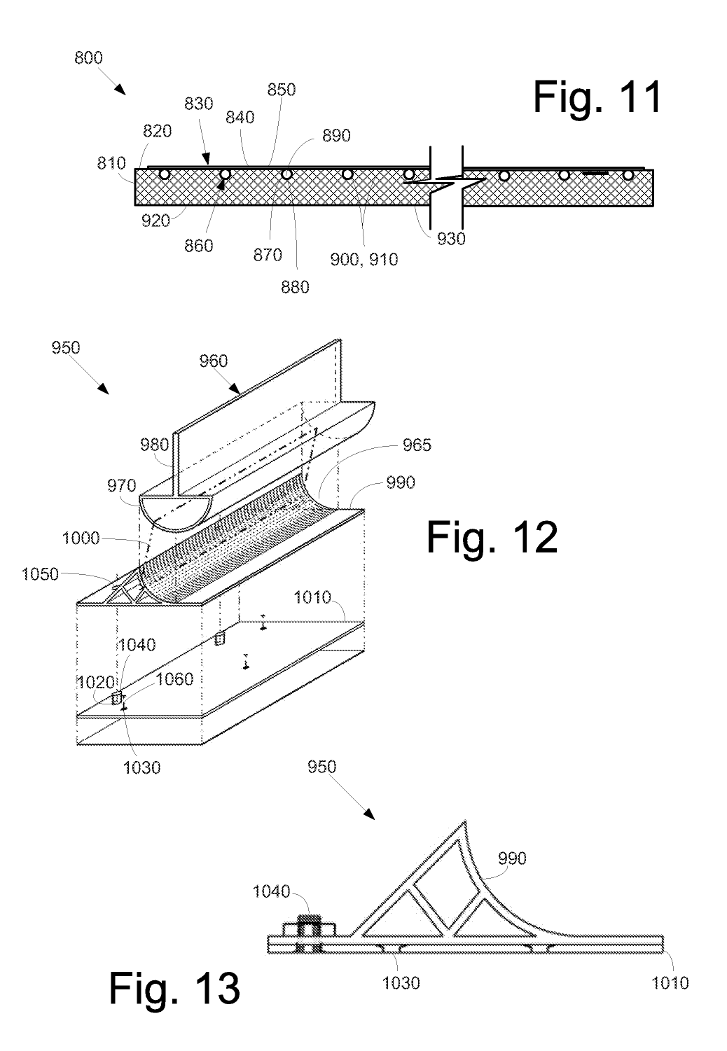

FIG. 11 shows an alternative embodiment of a solar panel system 800 as may be described herein. The solar panel system 800 may include an outer frame 810. The outer frame 810 may support a heat transfer plate 820. The heat transfer plate 820 may be relatively thin in dimension. The heat transfer plate 820 may be made out of aluminum or other types of lightweight, substantially rigid materials with good heat transfer characteristics.

The solar panel system 800 also may include a solar photovoltaic subsystem 830. The solar photovoltaic subsystem 830 may include a number of solar photovoltaic panels 840. The solar photovoltaic panels 840 may be a number of flexible, thin film or laminate panels 850 positioned on the heat transfer plate 820. Other types of solar photovoltaic panels 840 may be used herein. Other components and other configurations also may be used herein.

The solar panel system 800 also may include a solar thermal subsystem 860. The solar thermal subsystem 860 may include any number of heat exchange coils 870. In this example, the heat exchange coils 870 may be in the form of flexible tubing 880. The flexible tubing 880 may be considerably lighter than traditional rigid tubing made out of copper, aluminum, and the like. The flexible tubing 880 may be made out of a polycarbonate material and similar types of substantially flexible materials. A heat transfer medium 890 may flow therein. The nature of the heat transfer medium 890 may vary herein.

The heat exchange coils 870 may be positioned underneath the heat transfer plate 820 for contact and heat transfer therewith. One or more internal concentrator plate 900 may extend below the heat transfer plate 820 and/or encircle each of the heat exchange coils 870 in whole or in part. The concentrator plate 900 may be in the form of a mirror-like surface 910. The concentrator plate 900 has a high absorptance rate and transfers energy from the heat transfer plate 820 to the solar thermal subsystem 860. The concentrator plate 900 will reflect up to about 97% of the radiant heat of the sun. The internal concentrator plate 900 serves to focus radiant heat towards the heat transfer plate 820 in general and the heat exchange coils 870 in specific as well as to the solar photovoltaic panels 840. The internal concentrator plate 900 thus serves to boost the BTU output of the overall solar thermal subsystem 860 by a considerable percentage. The internal concentrator plate 900 may be made out of a metalized aluminum membrane, aluminum with a cooper oxide (CuO), and similar types of materials. Other components and other configurations may be used herein.

The heat exchange coils 870 may be positioned within an insulator 920. The insulator 920 may be in the form of a relatively rigid, lightweight foam and the like. Other types of insulators and insulation materials may be used herein. The insulator 920 may fill the interior of the outer frame 810 in whole or in part.

The solar panel system 800 also may include one or more external concentrator plate 930. The external concentrator plate 930 may be placed on a bottom of the outer frame 810, i.e., on the side opposite the photovoltaic panels 840. The external concentrator plate 930 serves to reflect sunlight from a first solar panel system 800 onto the photovoltaic subsystem 830 of an adjacent second solar panel system 800. The reflected sunlight thus serves to increase the output of the photovoltaic subsystem 830 in the second solar panel system 800. The external concentrator plate 930 also may be made out of a metalized aluminum membrane, aluminum with a cooper oxide (CuO), and similar types of materials. Other components and other configurations may be used herein.

The solar panel system 800 thus provides increased BTU output in a lightweight, low cost system. The internal concentrator plate 900 increases the BTU output of the solar thermal subsystem 860 while the external concentrator plate 930 increases the output of the adjacent photovoltaic subsystem 830. Likewise, the use of the flexible tubing 880 as the heat exchange coils 870 requires less overall weight and, hence, lower costs.

FIGS. 12 and 13 show an alternative embodiment of pivoting bracket assembly 950. The pivoting bracket assembly 950 may include a pivot bracket 960. The pivot bracket 960 may include a bottom U-shaped cup 970 with a top T-section 980 and/or similar shapes. The pivot bracket 960 may pivot within a pivot cradle 990. The pivot cradle 960 may have a complimentary curved shape 965 to accommodate the U-shaped cup 970 of the pivot bracket 960 for rotation therein. The pivot cradle 990 may be made out of aluminum or other types of substantially rigid materials. The pivot cradle 990 also may be made out of solid hard rubber and the like. The solid hard rubber provides good weather resistance and grounding. The pivot bracket 960 may be retained within the pivot cradle 990 via a pivot strap 1000. The pivot strap 1000 may be made out of a heat stabilized nylon material and/or other materials with good tensile strength and reasonable costs. Other components and other configurations may be used herein.

The pivot bracket assembly 950 also may include a roof mount plate 1010. The roof mount plate 1010 may include a number of pivot cradle anchor holes 1020 and a number of offset roof mount anchor holes 1030. A number of pivot cradle bolts 1040 may connect the pivot cradle 990 and the roof mount plate 1010 through the pivot cradle anchor holes 1020 and a number of aligning top anchor holes 1050. Likewise, a number of roof bolts 1060 may mount the pivot bracket assembly 950 via the roof mount anchor holes 1050. The roof mount anchor holes 1030 may include a counterbore. The use of the pivot cradle anchor holes 1020 and the offset roof mount anchor holes 1030 thus create multiple layers of water seals without an exposed penetration via the pivot cradle 990. The use of the multiple roof mount anchor holes 1030 also prevents twisting as shear stress is applied. Although three (3) roof mount anchor holes 1030 and bolts 1060 are used, any number may be used herein. A number of the pivot bracket assemblies 950 may be used together so as to provide redundant support. Other components and other configurations may be used herein.

It should be apparent that the foregoing relates only to certain embodiments of the present application and that nuoncruuo changes and modifications may be made herein by one of ordinary skill in the art without departing from the general spirit and scope of the invention as defined by the following claims and the equivalents thereof.

We claim:

1. An integrated solar panel system, comprising:
a heat transfer plate;
a solar photovoltaic subsystem positioned in part on the heat transfer plate; and
a solar thermal subsystem positioned beneath the heat transfer plate;
the solar thermal subsystem comprising one or more internal concentrator plates positioned about the heat transfer plate.

2. The integrated solar panel system of claim 1, wherein the solar photovoltaic subsystem comprises one or more flexible, thin film photovoltaic panels.

3. The integrated solar panel system of claim 1, wherein the solar thermal subsystem comprises a plurality of heat exchange coils positioned beneath the heat transfer plate.

4. The integrated solar panel system of claim 3, wherein plurality of heat exchange coils comprises a flexible tubing.

5. The integrated solar panel system of claim 3, wherein the one or more internal concentrator plates surround one or more of the plurality of heat exchange coils.

6. The integrated solar panel system of claim 1, wherein the one or more concentrator plates comprise a mirror-like system.

7. The integrated solar panel system of claim 1, further comprising an external concentrator plate.

8. The integrated solar panel system of claim 7, further comprising a plurality of adjacent solar panel systems such that the external concentrator plate of a first integrated solar panel system cooperates with the solar photovoltaic subsystem of a second integrated solar panel system.

9. The integrated solar panel system of claim 1, further comprising an outer frame and wherein the solar photovoltaic subsystem is positioned in part about the outer frame.

10. The integrated solar panel system of claim 1, further comprising an outer frame and wherein the solar thermal subsystem is positioned within the outer frame.

11. The integrated solar panel system of claim 10, further comprising a pivoting bracket assembly connected to the outer frame.

12. The integrated solar panel system of claim 11, wherein the pivoting bracket assembly comprises a pivot bracket and a nylon pivot strap.

13. The integrated solar panel system of claim 11, wherein the pivoting bracket assembly comprises a pivot cradle with a complimentary curved shape for use with the pivot bracket.

14. The integrated solar panel system of claim 11, wherein the pivoting bracket assembly comprises a roof mount plate mounted to the pivot cradle.

15. The integrated solar panel system of claim 14, wherein the roof mount plate comprises one or more offset roof mount anchor holes.

16. The integrated solar panel system of claim 15, wherein the offset roof mount anchor holes comprise a counterbore.

17. The integrated solar panel system of claim 1, wherein the solar photovoltaic subsystem comprises a plurality of color coded quick disconnect terminals.

18. An integrated solar panel system, comprising:
a heat transfer plate;
one or more flexible, thin film photovoltaic panels positioned on the heat transfer plate; and
a solar thermal subsystem positioned beneath the heat transfer plate;
the solar thermal subsystem comprising a plurality of heat exchange coils and one or more internal concentrator plates positioned beneath the heat transfer plate and the plurality of heat exchange coils.

19. The integrated solar panel system of claim 18, further comprising an external concentrator plate.

20. An integrated solar panel system, comprising:
an outer frame;
one or more flexible, thin film photovoltaic panels positioned about the outer frame;
a solar thermal subsystem positioned within the outer frame; and
a pivoting bracket assembly connected to the outer frame;
wherein the pivoting bracket assembly comprises a pivot bracket and a pivot cradle connected by a pivot strap.
